(19) United States
(12) Patent Application Publication
(10) Pub. No.: US 2026/0170227 A1
(43) Pub. Date: Jun. 18, 2026

(54) EFFICIENT FINITE CELL METHOD FOR STATIC ANALYSIS OF LATTICE STRUCTURES

(71) Applicant: DALIAN UNIVERSITY OF TECHNOLOGY, Dalian (CN)

(72) Inventors: Yonggang ZHENG, Dalian (CN); Weishuai LI, Dalian (CN); Weilong YANG, Dalian (CN); Hongfei YE, Dalian (CN); Shun ZHANG, Dalian (CN); Shuaiqi ZHANG, Dalian (CN); Yisong QIU, Dalian (CN)

(21) Appl. No.: 19/438,990

(22) Filed: Jan. 2, 2026

(30) Foreign Application Priority Data
Jun. 24, 2025 (CN) 202510849618.3

(51) Int. Cl. G06F 30/398; G06F 30/3323

(52) U.S. Cl. CPC G06F 30/398; G06F 30/3323

(57) ABSTRACT

The present invention belongs to the technical field of structural strength analysis methods for lattice structures, discloses an efficient finite cell method for static analysis of lattice structures, and establishes a high-efficiency and high-precision integrated method for finite element modeling and analysis of lattice structures. The present invention addresses the limitations of the difficulty in high-quality hex mesh generation and the need to ensure edge-fitted treatment for elements in traditional finite element analysis, adopts structured meshes for rapid mesh division, and improves the adaptive numerical integration strategy in the previous finite cell method, further enhancing the simulation efficiency. Meanwhile, the penalty function is adopted to weakly impose the displacement boundary conditions. In addition, the results calculated by the finite cell method are mapped into a smoother visualization model in post-processing. The present invention provides a feasible solution for the efficient analysis of large-scale complex engineering structures.

### TECHNICAL FIELD

The present invention belongs to the field of computational mechanics, and relates to an efficient finite cell method for static analysis of lattice structures.

### BACKGROUND

With the rapid development of equipment manufacturing industries such as automobiles, ships and aerospace, the demand for complex structures represented by hollow lattice structures in various industries is increasing day by day. Such structures are favored by the industries due to unique mechanical properties and structural features, which also makes the task of conducting structural strength analysis of complex structures more arduous. For a long time, the simulation analysis of structures has mostly relied on commercial finite element software such as ANSYS an ABAQUS, mesh division will directly affect the results, the most challenging structured hex mesh generation is still in the development stage, and hex mesh generation based on methods such as mapping and sweeping still cannot be fully automated. Therefore, the high-quality hex mesh generation of complex structures has become a serious obstacle to structural strength analysis using the finite element method.

Based on the finite cell method (FCM), efficient numerical simulation can be carried out for such complex structures, which expands the domain of computation into a simple rule structure in combination with the idea of virtual domains, and fast discretization is carried out using a regular structured mesh, without the need to ensure edge-fitted processing of elements, skipping the time-consuming and complex step of manually dividing the structured mesh. Thus, it is easy to meet the requirements of automatic and efficient discretization of any complex geometric structure. However, in the method, to accurately capture the discontinuities at the boundaries through the adaptive numerical integration, a large number of repetitive Boolean judgment operations are required, which reduces the efficiency of numerical simulation to a certain extent.

Therefore, based on the finite cell method, the present invention has been improved in the aspects such as mesh generation, stiffness matrix assembly (SMA) and post-processing, which can save the computational load and improve the computational efficiency. The present invention proposes a rapid and high-quality mesh generation method suitable for complex structures, and establishes a high-efficiency and high-precision integrated method for finite element modeling and analysis of lattice structures.

### SUMMARY

Aiming at the limitations of complex mesh division, large computational load and time-consuming simulation in the finite element analysis of lattice structures, the present invention innovatively proposes finite cell method software for static analysis (FCM-SA), with the purposes as follows: firstly, to overcome the limitations of dividing high-quality body-fitted meshes in the traditional finite element method (FEM), the present invention adopts voxelization operation to rapidly divide the model into high-quality internal, boundary and virtual cells; and secondly, to alleviate the phenomenon that the finite cell method generates a large number of Boolean operation judgments through the adaptive numerical integration to significantly reduce the calculation speed, the present invention improves the original finite cell method, and calculates and saves the information of all the Gaussian integration points (GIPs) in advance according to the situation of minimum partition in the adaptive numerical integration, which can meet the requirements of efficient calculation of complex structures. In addition, the present invention adopts the penalty function to weakly impose the Dirichlet boundary conditions, which solves the difficulty of not being able to directly impose boundary conditions to nodes due to the use of uniform mesh division. Finally, the present invention aims to alleviate the limitations of the existing finite element method, such as difficulty and high computational cost in dividing high-quality meshes when analyzing three-dimensional complex structures like lattice structures as well as low computational efficiency caused by a large number of Boolean judgments in the original finite cell method.

The technical solution of the present invention is as follows:

An efficient finite cell method for static analysis of lattice structures, comprising the following steps:
Step 1: conducting three-dimensional modeling of a complex lattice structure, and generating a voxelization model;
First, conducting three-dimensional modeling of a complex lattice structure, and generating a closed surface model; the closed surface model is enclosed by spatial triangular surfaces with an outer normal direction; and if the closed surface model has a very high degree of fit with the complex lattice structure, it is considered that a closed surface area Ω_{S} is consistent with a lattice structure area \tilde{Ω};
Then, conducting voxelized division based on the triangular surface information of the closed surface model, and generating a voxelization model; setting the length Lₓ, L_{y} and L_{z} of a voxelization area in x, y and z directions and the number nₓ, n_{y} and n_{z} of voxels, dividing the closed surface model into voxel blocks of the same size, and recording a geometric center coordinate matrix [Cen] and a vertex coordinate matrix [Node] of the voxel blocks; and numbering the voxel blocks and vertexes thereof, with the numbering rules as follows:

$${NumV}_{i} = fix ( \frac{{X}_{i}}{{L}_{x}} {n}_{x} ) + fix ( \frac{{Y}_{i}}{{L}_{y}} {n}_{y} ) {n}_{x} + fix ( \frac{{Z}_{i}}{{L}_{z}} {n}_{z} ) {n}_{x} {n}_{y} ( \qquad ( 1 )$$

$${NumN}_{i} = fix ( \frac{{x}_{i}}{{L}_{x}} {n}_{x} ) + 1 + fix ( \frac{{y}_{i}}{{L}_{y}} {n}_{y} ) ( {n}_{x} + 1 ) + fix ( \frac{{z}_{i}}{{L}_{z}} {n}_{z} ) ( {n}_{x} {n}_{y} + 1 ) ( \qquad ( 2 )$$

wherein NumVᵢ is the number of an i^{th} voxel block, fix represents rounding up to an integer, Xᵢ, Yᵢ and Zᵢ are geometric center coordinates of the i^{th} voxel block, NumNᵢ is the number of the vertex of the i^{th} voxel block, and xᵢ, yᵢ and zᵢ are vertex coordinates of the i^{th} voxel block; whether the geometric center of the voxel block is within the closed surface area Ω_{S} is determined according to the coordinates of the three vertexes of the triangular surfaces in the closed surface model and the information of the outer normal direction, the voxel blocks that are not within the closed surface area Ω_{S} are deleted, and the remaining voxel blocks and vertexes are reordered according to the numbers, thereby obtaining a voxelization model with voxel block numbers, vertex numbers and vertex coordinates; and the main difference between a space area occupied by the voxelization model and a space area occupied by the complex lattice structure lies in geometric boundaries, and the voxelization area is represented by Ω_{V};
Step 2: dividing a finite element adaptive quadrature mesh;
Defining a cuboid of such size that the voxelization area Ω_{V} in step 1 is fully embedded, wherein a space area occupied by the cuboid is called a global domain Ω, the cuboid is evenly divided along the coordinate axis direction to obtain a global finite element mesh model, and the size of the global finite element mesh model is larger than that of the voxel blocks; distinguishing elements in the global domain 22 as boundary elements, internal elements and external elements, wherein nodes corresponding to the elements are called boundary elements when not all within the voxelization area Ω_{V}; nodes corresponding to the elements are called internal elements when all within the voxelization area Ω_{V}; and nodes corresponding to the elements are called external elements when all outside the voxelization area Ω_{V}; and removing the boundary elements of the global finite element mesh model to obtain a basic finite element mesh model, i.e., a base mesh model, wherein the base mesh area Ω_{F} basically covers the voxelization area Ω_{V}, which can effectively represent the geometric shape of the lattice structure;
Further subdividing the boundary elements in the base mesh model into boundary elements containing subcells according to the rule of the octree subdivision method (octree); meanwhile, storing position coordinates of all the subcells in the boundary elements corresponding to GIPs, and changing the boundary elements where the number of the GIPs within the voxelization area Ω_{V} is less than one thousandth of the total number of GIPs to external elements; and removing all the external elements, and renumbering the elements and nodes of the base mesh model to obtain a base mesh model with the external elements removed, wherein the area occupied by the base mesh model is the base mesh area Ω_{F};
Step 3: calculating an element stiffness matrix (ESM) and a load vector, and assembling a global stiffness matrix and load vector;
According to the theory of the finite cell method, the calculation formula of the element stiffness matrix K^{e} is:

$${K}^{e} = {\int }_{{V}^{e}} β {B}^{T} DBdV \qquad ( 1 )$$

wherein V^{e} represents a space area occupied by the elements, the superscript T is a transposition symbol, β is a material penalty parameter, B is a strain matrix, and D is a constitutive matrix; and by using Gaussian quadrature, formula (3) is converted to a form of discrete summation as:

$${K}^{e} = {\int }_{{V}^{e}} β {B}^{T} DBdV = {\sum }_{g = 1}^{{n}_{g}} {β}_{g} {B}^{T} DB \vert {J}_{Q} \vert \vert {J}_{q} \vert {w}_{g} \qquad ( 2 )$$

wherein g is the number of a GIP within an element, n_{g} is the total number of GIPs within the element, w_{g} is an integral weight corresponding to the GIP g, and β_{g} is a penalty parameter of the GIP g; if the GIP g is within the voxelization area Ω_{V}, then β_{g}=1; otherwise, β_{g}=0, and only the GIPs within the boundary elements are judged; in addition, an eight-node linear element is adopted, that is, each element contains eight GIPs; and |J_{Q}| and |J_{q}| are respectively determinants of Jacobian matrixes of two coordinate changes from a global coordinate system (the coordinates of the GIP relative to the origin of the finite element) X, Y and Z to an element coordinate system (the coordinates of the GIP relative to the geometric center of the element) x, y and z and from the element coordinate system x, y and z to an integration subcell coordinate system (the coordinates of the GIP relative to the geometric center of the subcell) ξ, η and ζ, wherein the formulas of the two coordinate changes are:

$$[ \begin{matrix}X \\ Y \\ Z\end{matrix} \text{} ] = [ \begin{matrix}{X}_{1} + ( \frac{1}{2} + x ) {h}_{x} \\ {Y}_{1} + ( \frac{1}{2} + y ) {h}_{y} \\ {Z}_{1} + ( \frac{1}{2} + z ) {h}_{z}\end{matrix} \text{} ] , [ \begin{matrix}x \\ y \\ z\end{matrix} \text{} ] = [ \begin{matrix}{x}_{1} + ( \frac{1}{2} + ξ ) {h}_{ξ} \\ {y}_{1} + ( \frac{1}{2} + η ) {h}_{η} \\ {z}_{1} + ( \frac{1}{2} + ζ ) {h}_{ζ}\end{matrix} \text{} ] \qquad ( 3 )$$

wherein X₁, Y₁ and Z₁ are the global coordinate system of the node at the lower left corner of the element, x₁, y₁ and z₁ are the element coordinate system of the node at the lower left corner of the subcell, hₓ, h_{y} and h_{z} are respectively the length of the element in the x, y and z directions, and h_{ξ}, h_{η} and h_{ζ} are respectively the length of the subcell in ξ, η and ζ directions; and then, |J_{Q}| and |J_{q}| are respectively calculated as follows:

$$\vert {J}_{Q} \vert = \frac{1}{2} \vert \text{} \begin{matrix}\frac{\partial X}{\partial x} & \frac{\partial X}{\partial y} & \frac{\partial X}{\partial z} \\ \frac{\partial Y}{\partial x} & \frac{\partial Y}{\partial y} & \frac{\partial Y}{\partial z} \\ \frac{\partial Z}{\partial x} & \frac{\partial Z}{\partial y} & \frac{\partial Z}{\partial z}\end{matrix} \text{} \vert = \frac{1}{2} \vert \text{} \begin{matrix}{h}_{x} & 0 & 0 \\ 0 & {h}_{y} & 0 \\ 0 & 0 & {h}_{z}\end{matrix} \text{} \vert \qquad ( 4 )$$

$$\vert {J}_{q} \vert = \frac{1}{2} \vert \text{} \begin{matrix}\frac{\partial x}{\partial ξ} & \frac{\partial x}{\partial η} & \frac{\partial x}{\partial ζ} \\ \frac{\partial y}{\partial ξ} & \frac{\partial y}{\partial η} & \frac{\partial y}{\partial ζ} \\ \frac{\partial z}{\partial ξ} & \frac{\partial z}{\partial η} & \frac{\partial z}{\partial ζ}\end{matrix} \text{} \vert = \frac{1}{2} \vert \text{} \begin{matrix}{h}_{ξ} & 0 & 0 \\ 0 & {h}_{η} & 0 \\ 0 & 0 & {h}_{ζ}\end{matrix} \text{} \vert$$

Calculating the element stiffness matrixes of all the elements according to formulas (4)-(6), and assembling a global stiffness matrix; and since B^{T}DB|J_{Q}∥J_{q}| corresponding to GIPs at the same position in elements of the same size is the same, classifying the GIPs according to the relative positions thereof within the elements, i.e., the sizes of the elements, and only needing to calculate the B^{T}DB|J_{Q}∥J_{q}| corresponding to different types of GIPs;
After obtaining the element stiffness matrix of each element, assembling a global stiffness matrix K according to the corresponding node numbers;
Step 4: adopting imposition of boundary conditions in the weak form;
Step 5: calculating and outputting a result file for post-processing.

Further, in step 4, since the base mesh model generated by the finite cell method has a sawtooth shape at the boundaries, and nodes of the boundary elements are not at the actual smooth boundaries, step 4 in claim 1 cannot be directly implemented; and to achieve the weak imposition of boundary conditions of a surface load, force boundary conditions are imposed by a Gaussian quadrature Lagrange polynomial interpolation weak imposition method, and displacement boundary conditions are imposed by a penalty function;
For the imposition of force boundary conditions in the weak form: the shape of the actual smooth surface of the surface load is simplified according to the engineering practice, the surface is discretized into a triangular surface composed of triangles, and the vertex coordinates of each triangle in the triangular surface are extracted; at this time, the area where the surface is located is not completely within the boundary elements of the base mesh model; the boundary of the surface load is simplified into a function t̅ varying in the global coordinate system; and the triangular surface is subjected to isoparametric transformation to obtain a two-dimensional square isoparametric element, and the two-dimensional square isoparametric element is integrated through a surface force load to obtain an equivalent node load

$${F}_{c 1}^{\overline{t}}$$

or the boundary elements;

$$[ {F}_{c 1}^{\overline{t}} ] = {\sum }_{l = 1}^{{n}_{cl}} {\int }_{v} {\int }_{u} {N}_{{c}_{1}}^{T} ( γ ) \overline{t} \vert {u}_{u}^{l} ( u , v ) \times {u}_{v}^{l} ( u , v ) \vert du dv \qquad ( 7 )$$

wherein c₁ is the number of an element in the base mesh model where the vertexes of the triangles are located, l is the serial number of the triangular surface, and n_{cl} is the total number of the triangles;

$${N}_{{c}_{1}}^{T}$$

is the transposition of the matrix of the shape function for displacement of the element in the base mesh model, and

$$γ = {Q}_{{c}_{1}}^{- 1} ( {u}^{l} ( u , v ) )$$

is the inverse transformation from the element coordinate system x to the local coordinate u in the two-dimensional square isoparametric element, i.e., the coordinates u and v in the two-dimensional isoparametric element are transformed into local coordinates x, y and z in the element of the base mesh model through the transformation; u(u, v) is a coordinate vector function in the two-dimensional square isoparametric element, and is obtained through the transformation of

$${u}^{l} = {Q}_{{c}_{1}} ( u , v ) = {\sum }_{gt = 1}^{4} {N}_{gt} ( u , v ) {x}_{gt} ,$$

N_{gt}(u, v) is the shape function for displacement of a gt^{th} node of the two-dimensional square isoparametric element, and x_{gt} is the local coordinate of a corresponding square isoparametric element node in the elements of the base mesh model;

$${u}_{v}^{l} ( u , v ) \times {u}_{v}^{l} ( u , v )$$

is the partial derivative and multiplication cross of the u coordinate vector of an l^{th} triangle with respect to the u direction and the v direction respectively; and ∥ is the determinant of a matrix, and due to the complexity of the actual surface, the functional form thereof is mostly an integral expression without an exact form, so numerical integration is carried out using Gaussian quadrature:

$$[ {F}_{{c}_{1}}^{\overline{t}} ] = {\sum }_{l = 1}^{{n}_{cl}} {\sum }_{j = 1}^{{n}_{t} = 4} {N}_{{c}_{1}}^{T} ( {x}_{j} , {y}_{j} , {z}_{j} ) \overline{t} ( {X}_{j} , {Y}_{j} , {Z}_{j} ) det {J}_{lj} {w}_{j} \qquad ( 9 )$$

wherein nₜ is the number of GIPs in the two-dimensional square isoparametric element, det Jₗⱼ is the determinant of a Jacobian transformation matrix of a j^{th} GIP of the surface load of the l^{th} triangle, and wⱼ is the integral weight of a j^{th} relative GIP position during Gaussian quadrature; and after the calculation of an element load matrix in the base mesh model is completed, a global load vector R is assembled according to the node numbers of the base mesh model;
For the imposition of Dirichlet displacement boundary conditions in the weak form, it is necessary to correct a total potential energy functional Π* by the penalty function, so as to achieve the weak imposition of displacement constraint conditions, and the following displacement constraint conditions are considered:

$$GU = V \qquad ( 10 )$$

wherein G is a total shape function matrix corresponding to a constrained point, U is a total node displacement vector, and V is a constraint value;
The corrected energy functional Π* is expressed as:

$${\prod }^{*} = \frac{1}{2} {U}^{T} KU - {U}^{T} R + \frac{1}{2} {α ( GU - V )}^{T} ( GU - V ) \qquad ( 11 )$$

wherein K is a global stiffness matrix, and α is a penalty function factor;
The extreme value of the corrected functional Π* is taken to obtain the following equation of static equilibrium:

$$( K + {αG}^{T} G ) U = R + {αG}^{T} V \qquad ( 12 )$$

The equation is expressed as a standard equilibrium equation:

$${K}^{*} U = {R}^{*} \qquad ( 13 )$$

wherein K* is a global stiffness matrix after the imposition of the boundary conditions, and R* is a load vector after the imposition of the boundary conditions;
The process of solving a displacement in mechanics is regarded as solving a definite solution problem ( [symbol] ) containing the boundary conditions; considering the lattice structure area \tilde{Ω} in step 1, which is hereinafter referred to as an actual smooth domain \tilde{Ω}, the global domain Ω in step 2 and an actual embedding domain Ωₑ=Ω−\tilde{Ω}, the boundary surface of Ωₑ is ∂\tilde{Ω}; and the definite solution problem is presented in a mathematical expression as:

$$( 𝓅 ) \{ \begin{matrix}- div ( \tilde{a} \cdot ∇ \tilde{u} ) + \tilde{b} \tilde{a} = \tilde{f} & in \tilde{Ω} \\ BC & on \partial \tilde{Ω}\end{matrix} \qquad ( 14 )$$

wherein div is vector divergence, ã is a diffusion tensor, ∇ is a Hamiltonian operator, ũ is an actual boundary displacement, \tilde{b} is a penalty value of the penalty function, \tilde{f} is a corrected volume force of the penalty function, and BC is an actual boundary condition; and when the boundary condition of the definite solution problem is the Dirichlet displacement boundary condition, the ũ boundary body displacement in \tilde{Ω} is simplified into a displacement u_{D} only considering the boundary surface ∂\tilde{Ω}, i.e., ũ=u_{D};
When the problem is considered using the finite cell method, since consistent meshes are used for division, the embedding domain and the actual domain are composed of consistent meshes, and the shapes thereof are different from the smooth shape of the actual embedding domain and the actual smooth domain in the original problem to the sawtooth shape; therefore, various areas originally used for calculation and analysis in the problem are changed accordingly, the actual embedding domain Ωₑ is changed to an embedding domain Ω_{e,h}, and the actual smooth domain \tilde{Ω} is changed to an actual domain \tilde{Ω}ₕ∪ω_{h,Σ}, wherein \ddot{Ω}ₕ is an internal domain composed of all the internal elements, ω_{h,Σ} is an area occupied by all the boundary elements, and Σ is a partial boundary surface within the boundary elements; and the problem ( [symbol] ) solved in the global domain [symbol] Ω has the following general form: a specific penalty value coefficient 0<η≤1 is selected to perform calculation in the global domain Ω to obtain a problem of imposing a true equivalent displacement

$${u}_{η}^{h} ,$$

the magnitude thereof is specifically determined by the volume of the actual smooth domain truncated by each boundary element, and the definite solution problem within the global domain Ω is transformed into:

$$( 𝓅 ) \{ \begin{matrix}- div ( a \cdot ∇ {u}_{η}^{h} ) + {bu}_{η}^{h} = f & in \tilde{Ω} \\ Original boundary of problem ( 𝓅 ) & on \partial \tilde{Ω} \\ Boundary of equivalent displacement {u}_{η}^{h} & on {ω}_{h , Σ}\end{matrix} \qquad ( 15 )$$

wherein a∈(L^{∞}(Ω))^{d}^{²}, b∈L^{∞}(Ω), and f∈L²(Ω), i.e., a diffusion tensor a belongs to a (L^{∞}(Ω))^{d}^{²} tensor set, a penalty coefficient b belongs to a L^{∞}(Ω) number set, and an equivalent volume force f belongs to a L²(Ω) two-directional number set; and the integral values of the simplified diffusion tensor a, penalty coefficient b and equivalent volume force f in the internal domain \tilde{Ω}ₕ are the same as those of the corresponding actual values in the actual smooth domain \tilde{Ω};
For the Dirichlet displacement boundary conditions in the finite cell method, the penalty coefficient b and the equivalent volume force f of the boundary element are respectively:

$$b = \frac{1}{η} , f = \frac{1}{η} {u}_{D} witin {ω}_{h , Σ} \qquad ( 16 )$$

wherein

$$η = \frac{meas ( Σ )}{meas ( {ω}_{h , Σ}^{m} )} , meas ( {ω}_{h , Σ}^{m} )$$

is the volume of an m^{th} boundary element, and meas(Σ) is the volume of the boundary element within the boundary surface Σ; and a planar rectangular area perpendicular to the coordinate axis is defined, the boundary element is retrieved in the direction perpendicular to the rectangular area, and the imposition of the displacement boundary conditions is carried out using formula (16) to obtain the global stiffness matrix K* and the load vector R* after the imposition of the boundary conditions.

Further, in step 5, the displacement result U of a base mesh node is calculated through formula (10) in claim 2, and a stress-strain value is calculated; the closed surface model of the complex lattice structure is imported into Hypermesh for body-fitted mesh modeling to generate a tetrahedral body-fitted mesh model; the results on the nodes of the base mesh model are respectively mapped to the voxelization model and a tetrahedral edge-fitted model; and the physical information of an o^{th} node of the tetrahedral body-fitted mesh is denoted as pₒ, N_{Io} is the shape function for displacement of an I^{th} node in the base mesh model, and the displacement, strain and stress values of the nodes in the tetrahedral body-fitted mesh are subjected to result mapping according to N_{Io}, that is:

$${p}_{I} = {N}_{Io} {P}_{o} \qquad ( 17 )$$

The physical information pₒ comprises node displacement, strain and stress values; and a stress smoothing method is adopted, and when the degree of smoothing grinding is considered to be a(0<a<1), a smoothing grinding formula is:

$$\{ \begin{matrix}{σ}_{I}^{r} = {\sum }_{k = 1}^{{n}_{k}} \frac{{\sum }_{g = 1}^{{n}_{g}} {β}_{g}^{{c}_{2}}}{{\sum }_{k = 1}^{{n}_{k}} {\sum }_{g = 1}^{{n}_{g}} {β}_{g}^{k}} {σ}_{I}^{{c}_{2}} & if 0 < \tilde{ϵ} \leq ϵ \\ {σ}_{I}^{r} = {σ}_{I}^{{c}_{2}} & if ϵ < \tilde{ϵ}\end{matrix} \qquad ( 18 )$$

wherein

$${σ}_{I}^{{c}_{2}}$$

is the stress value of the I^{th} node in a c₂^{th} element of the base mesh model, σ_{I}^{r} is a smoothed stress value, nₖ is the number of tetrahedral meshes containing the I^{th} node,

$${β}_{g}^{{c}_{2}}$$

is a penalty function index of a g^{th} GIP penalty function in the c₂^{th} element,

$${β}_{g}^{k}$$

is a penalty function index of a g^{th} GIP in the k^{th} element, \tilde{ϵ} is the proportion of the stress value of the node corresponding to the c₂^{th} element in the global stress variation, no smoothing is performed when the index \tilde{ϵ} of the node is less than a defined index ϵ, and \tilde{ϵ} is defined as:

$$\tilde{ϵ} = \frac{\vert {σ}_{I}^{r} - {σ}_{I}^{{c}_{2}} \vert}{\vert {σ}_{g , max} - {σ}_{g , min} \vert} \qquad ( 19 )$$

wherein σ_{g,max} is global maximum stress, σ_{g,min} is global minimum stress, and |⋅| represents taking an absolute value;
Since the external elements are removed in step 2, mesh nodes located outside the base mesh area Ω_{F} will exist on the tetrahedral body-fitted mesh; since the use of the shape function for displacement of the elements requires the interpolated points to be within the elements of the base mesh area Ω_{F}, the nodes located outside the base mesh area Ω_{F} cannot be directly subjected to result mapping through the shape function for displacement N_{Io}, and such problems are solved based on the basic principles of the natural neighbor interpolation (NNI) in the method; and if a node on a tetrahedral body-fitted mesh is outside the base mesh area Ω_{F} when the retrieved element is subjected to result mapping, the global coordinate system X, Y, Z of the node is listed separately, all elements close to the node are retrieved, and the distance [Cen] between the geometric center position d of the elements and the node is calculated as:

$$[ Dis ] = \sqrt{{( ( X , Y , Z ) - [ Cen ] )}^{2}} \qquad ( 20 )$$

The boundary element closest to the node is judged by the distance [Dis], and the displacement, strain and stress values of the node within the boundary element are subjected to result mapping to obtain a smooth result output, so as to solve the problem of stress result distortion.

The present invention has the following beneficial effects:

(1) The structured mesh division method provided by the present invention provides a simple and efficient discretization method for hollow lattice filling structures, rapidly achieving uniform mesh discretization and breaking through the limitation that such structures require a large amount of time and cost for mesh generation. Through structured mesh division, the edge-fitted processing of the mesh is avoided, the workload of preprocessing is reduced, and the mechanical response of complex models is rapidly preprocessed and calculated and can be directly expanded to the mesh generation of other complex engineering structures, such as engine blades, heat sinks and wings.

(2) The boundary cell integration strategy provided by the present invention divides the boundary cell into multiple small sub-integral domains, and calculates and stores the shape function and strain-displacement matrix of each GIP in advance, which can effectively capture the discontinuities of the integral domain of the boundary cell. Compared with the “octree” adaptive numerical integration strategy in the previous finite cell methods, the method avoids the repeated loop of internal and external Boolean judgments, thereby significantly reducing the computational load, which can meet the requirements of rapid calculation in complex structures and improve the computational efficiency. The integration strategy can also be extended to other integration calculations with large variation gradients, for example, in the researches such as topology optimization and phase-field fracture.

(3) The boundary condition imposition method provided by the present invention adopts the penalty function to correct the total potential energy functional and weakly imposes the displacement boundary conditions, which solves the problem that the boundary conditions cannot be directly imposed through cell nodes due to structured mesh division, and the displacement boundary conditions are approximately imposed on the nodes, which provides technical support for the imposition of boundaries in complex geometric structures.

(4) The efficient finite cell method for static analysis of lattice structures provided by the present invention develops a rapid and high-quality mesh division modeling method suitable for complex structures, improves the imposition method for boundary conditions, establishes a high-efficiency and high-precision integrated method for finite element modeling and analysis of complex hollow lattice structures, and also provides a feasible solution for the efficient analysis of large-scale complex engineering structures.

### DESCRIPTION OF DRAWINGS

FIG. 1 is a flow chart of steps of the present invention;

FIG. 2 shows a result of structured mesh generation of a three-dimensional lattice structure of embodiment 1 of the present invention;

FIG. 3 shows results of energy analysis of a three-dimensional lattice structure of embodiment 1 of the present invention: a) a global displacement nephogram; b) an oblique section displacement nephogram; c) a global stress nephogram; d) an oblique section stress nephogram.

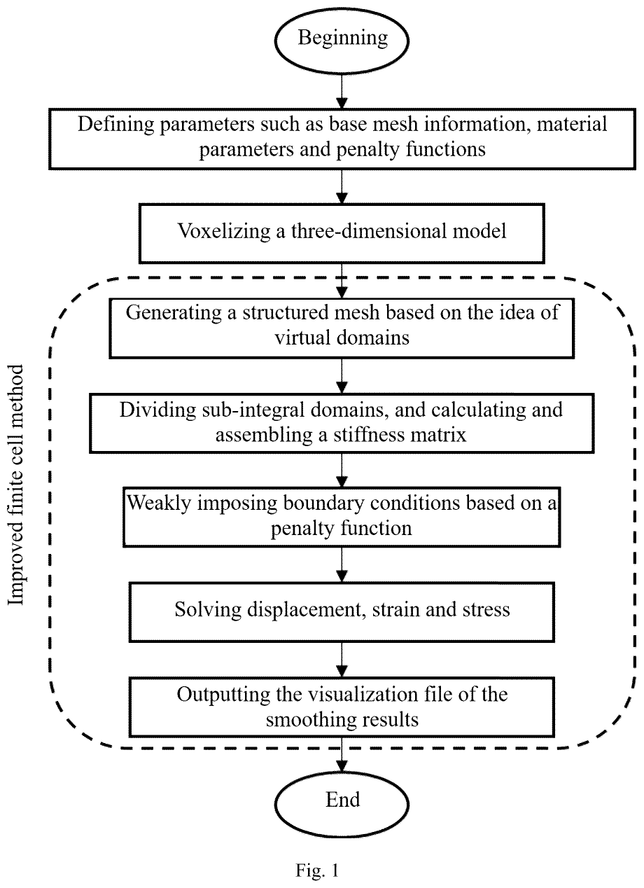

### DETAILED DESCRIPTION

Specific embodiments of the present invention are further described below in combination with the drawings and the technical solution.

### EMBODIMENTS

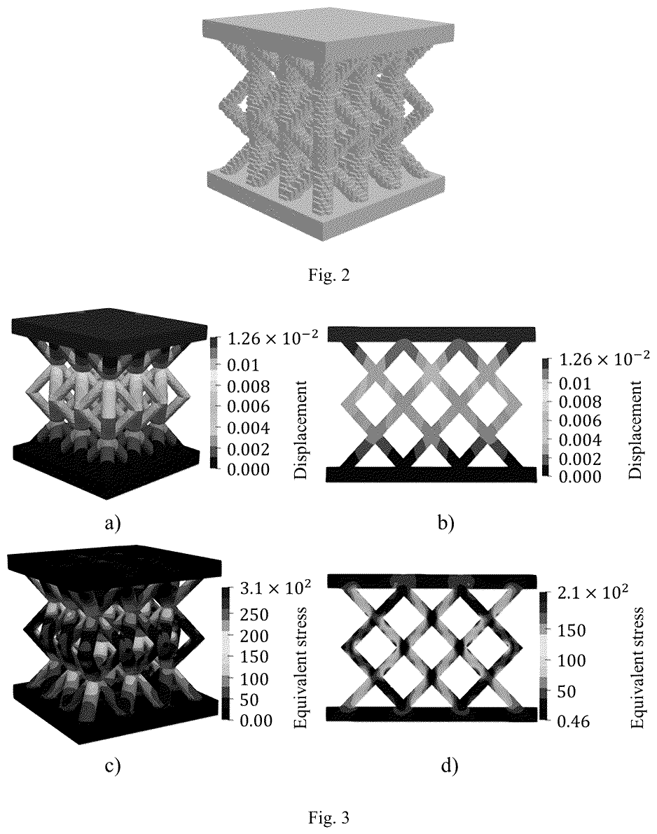

The accuracy, reliability and excellent performance of the efficient finite cell method for static analysis of lattice structures proposed in the present invention are further described in detail in combination with FIG. 2 to FIG. 3.

In the embodiments, a three-dimensional hollow lattice structure of 20 mm*20 mm*20 mm shown in FIG. 2 is simulated, the upper end and the lower end are both in a plate-shaped structure, the middle part is in a hollow rod-shaped structure with a radius of 1 mm, the lower surface is fixed, and a vertical downward surface force is applied to the upper surface. The material parameters are taken: Young's modulus E=210 GPa and Poisson's ratio v=0.3. In the present invention, voxel data is taken as an input file, and regular hex cells are rapidly discretized into 60*60*60 elements. During the simulation process, virtual cells that are completely in virtual domains are not considered, and only real cells and boundary cells are involved in the calculation, achieving a reduction in the computational scale. In FIG. 3, the displacement nephogram and the stress nephogram of the lattice structure are presented. Compared with the results calculated by the commercial software Abaqus, the method can efficiently and accurately conduct static analysis of complex lattice structures. Therefore, the efficient finite cell method for static analysis of lattice structures proposed by the present invention can conduct efficient numerical simulation studies of such structures, quickly achieves uniform mesh discretization, and has high precision and solution efficiency, which can provide effective technical support for the simulation analysis of typical 3D additive manufacturing lattice filling structures.

Embodiments of the present invention are given for example and description purposes, but are not exhaustive or used to limit the present invention to the disclosed forms. Many modifications and changes are apparent to those skilled in the art. The purpose of selecting and describing the embodiments is to preferably illustrate the principles and practical applications of the present invention, so that those skilled in the art can understand the present invention, thereby designing various modified embodiments applied to specific uses.

1. An efficient finite cell method for static analysis of lattice structures, comprising the following steps:
step 1: conducting three-dimensional modeling of a complex lattice structure, and generating a voxelization model;
first, conducting three-dimensional modeling of a complex lattice structure, and generating a closed surface model; the closed surface model is enclosed by spatial triangular surfaces with an outer normal direction; and if the closed surface model has a very high degree of fit with the complex lattice structure, it is considered that a closed surface area Ω_{S} is consistent with a lattice structure area \tilde{Ω};
then, conducting voxelized division based on the triangular surface information of the closed surface model, and generating a voxelization model; setting the length Lₓ, L_{y} and L_{z} of a voxelization area in x, y and z directions and the number nₓ, n_{y} and n_{z} of voxels, dividing the closed surface model into voxel blocks of the same size, and recording a geometric center coordinate matrix [Cen] and a vertex coordinate matrix [Node] of the voxel blocks; and numbering the voxel blocks and vertexes thereof, with the numbering rules as follows:
$${NumV}_{i} = fix ( \frac{{X}_{i}}{{L}_{x}} {n}_{x} ) + fix ( \frac{{Y}_{i}}{{L}_{y}} {n}_{y} ) {n}_{x} + fix ( \frac{{Z}_{i}}{{L}_{z}} {n}_{z} ) {n}_{x} {n}_{y} \qquad ( 5 )$$
$${NumV}_{i} = fix ( \frac{{x}_{i}}{{L}_{x}} {n}_{x} ) + 1 + fix ( \frac{{y}_{i}}{{L}_{y}} {n}_{y} ) ( {n}_{x} + 1 ) + fix ( \frac{{z}_{i}}{{L}_{z}} {n}_{z} ) ( {n}_{x} {n}_{y} + 1 ) \qquad ( 6 )$$
wherein NumVᵢ is the number of an i^{th} voxel block, fix represents rounding up to an integer, Xᵢ, Yᵢ and Zᵢ are geometric center coordinates of the i^{th} voxel block, NumNᵢ is the number of the vertex of the i^{th} voxel block, and xᵢ, yᵢ and zᵢ are vertex coordinates of the i^{th} voxel block; whether the geometric center of the voxel block is within the closed surface area Ω_{S} is determined according to the coordinates of the three vertexes of the triangular surfaces in the closed surface model and the information of the outer normal direction, the voxel blocks that are not within the closed surface area Ω_{S} are deleted, and the remaining voxel blocks and vertexes are reordered according to the numbers, thereby obtaining a voxelization model with voxel block numbers, vertex numbers and vertex coordinates; and the main difference between a space area occupied by the voxelization model and a space area occupied by the complex lattice structure lies in geometric boundaries, and the voxelization area is represented by Ω_{V};
step 2: dividing a finite element adaptive quadrature mesh;
defining a cuboid of such size that the voxelization area Ω_{V} in step 1 is fully embedded, wherein a space area occupied by the cuboid is called a global domain Ω, the cuboid is evenly divided along the coordinate axis direction to obtain a global finite element mesh model, and the size of the global finite element mesh model is larger than that of the voxel blocks; distinguishing elements in the global domain Ω as boundary elements, internal elements and external elements, wherein nodes corresponding to the elements are called boundary elements when not all within the voxelization area Ω_{V}; nodes corresponding to the elements are called internal elements when all within the voxelization area Ω_{V}; and nodes corresponding to the elements are called external elements when all outside the voxelization area Ω_{V}; and removing the boundary elements of the global finite element mesh model to obtain a basic finite element mesh model, i.e., a base mesh model, wherein the base mesh area Ω_{F} basically covers the voxelization area Ω_{V}, which can effectively represent the geometric shape of the lattice structure;
further subdividing the boundary elements in the base mesh model into boundary elements containing subcells according to the rule of the octree subdivision method (octree); meanwhile, storing position coordinates of all the subcells in the boundary elements corresponding to Gaussian integration points (GIPs), and changing the boundary elements where the number of the GIPs within the voxelization area Ω_{V} is less than one thousandth of the total number of GIPs to external elements; and removing all the external elements, and renumbering the elements and nodes of the base mesh model to obtain a base mesh model with the external elements removed, wherein the area occupied by the base mesh model is the base mesh area Ω_{F};
step 3: calculating an element stiffness matrix (ESM) and a load vector, and assembling a global stiffness matrix and load vector;
according to the theory of the finite cell method, the calculation formula of the element stiffness matrix K^{e} is:
$${K}^{e} = {\int }_{{V}^{e}} β {B}^{T} DBdV \qquad ( 7 )$$
wherein V^{e} represents a space area occupied by the elements, the superscript T is a transposition symbol, β is a material penalty parameter, B is a strain matrix, and D is a constitutive matrix; and by using Gaussian quadrature, formula (3) is converted to a form of discrete summation as:
$${K}^{e} = {\int }_{{V}^{e}} β {B}^{T} DBdV = {\sum }_{g = 1}^{{n}_{g}} {β}_{g} {B}^{T} DB \vert {J}_{Q} \vert \vert {J}_{q} \vert {w}_{g} \qquad ( 8 )$$
wherein g is the number of a GIP within an element, n_{g} is the total number of GIPs within the element, w_{g} is an integral weight corresponding to the GIP g, and β_{g} is a penalty parameter of the GIP g; if the GIP g is within the voxelization area Ω_{V}, then β_{g}=1; otherwise, β_{g}=0, and only the GIPs within the boundary elements are judged; in addition, an eight-node linear element is adopted, that is, each element contains eight GIPs; and |J_{Q}| and |J_{q}| are respectively determinants of Jacobian matrixes of two coordinate changes from a global coordinate system (the coordinates of the GIP relative to the origin of the finite element) X, Y and Z to an element coordinate system (the coordinates of the GIP relative to the geometric center of the element) x, y and z and from the element coordinate system x, y and z to an integration subcell coordinate system (the coordinates of the GIP relative to the geometric center of the subcell ξ, η and ζ, wherein the formulas of the two coordinate changes are:
$$[ \begin{matrix}X \\ Y \\ Z\end{matrix} ] = [ \begin{matrix}{X}_{1} + ( \frac{1}{2} + x ) {h}_{x} \\ {Y}_{1} + ( \frac{1}{2} + y ) {h}_{y} \\ {Z}_{1} + ( \frac{1}{2} + z ) {h}_{z}\end{matrix} ] , [ \begin{matrix}x \\ y \\ z\end{matrix} ] = [ \begin{matrix}{x}_{1} + ( \frac{1}{2} + ξ ) {h}_{ξ} \\ {y}_{1} + ( \frac{1}{2} + η ) {h}_{η} \\ {z}_{1} + ( \frac{1}{2} + ζ ) {h}_{ζ}\end{matrix} ] \qquad ( 9 )$$
wherein X₁, Y₁ and Z₁ are the global coordinate system of the node at the lower left corner of the element, x₁, y₁ and z₁ are the element coordinate system of the node at the lower left corner of the subcell, hₓ, h_{y} and h_{z} are respectively the length of the element in the x, y and z directions, and h_{ξ}, h_{η} and h_{ζ} are respectively the length of the subcell in ξ, η and ζ directions; and then, |J_{Q}| and |J_{q}| are respectively calculated as follows:
$$\vert {J}_{Q} \vert = \frac{1}{2} \vert \begin{matrix}\frac{\partial X}{\partial x} & \frac{\partial X}{\partial y} & \frac{\partial X}{\partial z} \\ \frac{\partial Y}{\partial x} & \frac{\partial Y}{\partial y} & \frac{\partial Y}{\partial z} \\ \frac{\partial Z}{\partial x} & \frac{\partial Z}{\partial y} & \frac{\partial Z}{\partial z}\end{matrix} \vert = \frac{1}{2} \vert \begin{matrix}{h}_{x} & 0 & 0 \\ 0 & {h}_{y} & 0 \\ 0 & 0 & {h}_{z}\end{matrix} \vert \qquad ( 10 )$$
$$\vert {J}_{q} \vert = \frac{1}{2} \vert \begin{matrix}\frac{\partial x}{\partial ξ} & \frac{\partial x}{\partial η} & \frac{\partial x}{\partial ζ} \\ \frac{\partial y}{\partial ξ} & \frac{\partial y}{\partial η} & \frac{\partial y}{\partial ζ} \\ \frac{\partial z}{\partial ξ} & \frac{\partial z}{\partial η} & \frac{\partial z}{\partial ζ}\end{matrix} \vert = \frac{1}{2} \vert \begin{matrix}{h}_{ξ} & 0 & 0 \\ 0 & {h}_{η} & 0 \\ 0 & 0 & {h}_{ζ}\end{matrix} \vert$$
calculating the element stiffness matrixes of all the elements according to formulas (4)-(6), and assembling a global stiffness matrix; and since B^{T}DB|J_{Q}∥J_{q}| corresponding to GIPs at the same position in elements of the same size is the same, classifying the GIPs according to the relative positions thereof within the elements, i.e., the sizes of the elements, and only needing to calculate the B^{T}DB|J_{Q}∥J_{q}| corresponding to different types of GIPs;
after obtaining the element stiffness matrix of each element, assembling a global stiffness matrix K according to the corresponding node numbers;
step 4: adopting imposition of boundary conditions in the weak form;
step 5: calculating and outputting a result file for post-processing.

2. The efficient finite cell method for static analysis of lattice structures according to claim 1, wherein
in step 4, since the base mesh model generated by the finite cell method has a sawtooth shape at the boundaries, and nodes of the boundary elements are not at the actual smooth boundaries, step 4 in claim 1 cannot be directly implemented; and to achieve the weak imposition of boundary conditions of a surface load, force boundary conditions are imposed by a Gaussian quadrature Lagrange polynomial interpolation weak imposition method, and displacement boundary conditions are imposed by a penalty function;
for the imposition of force boundary conditions in the weak form: the shape of the actual smooth surface of the surface load is simplified according to the engineering practice, the surface is discretized into a triangular surface composed of triangles, and the vertex coordinates of each triangle in the triangular surface are extracted; at this time, the area where the surface is located is not completely within the boundary elements of the base mesh model; the boundary of the surface load is simplified into a function t̅ varying in the global coordinate system; and the triangular surface is subjected to isoparametric transformation to obtain a two-dimensional square isoparametric element, and the two-dimensional square isoparametric element is integrated through a surface force load to obtain an equivalent node load
$${F}_{c 1}^{\overline{t}}$$
or the boundary elements;
$$[ {F}_{{c}_{1}}^{\overline{t}} ] = {\sum }_{l = 1}^{{n}_{cl}} {\int }_{v} {\int }_{u} {N}_{{c}_{1}}^{T} ( γ ) \overline{t} \vert {u}_{v}^{l} ( u , v ) \times {u}_{v}^{l} ( u , v ) \vert du dv \qquad ( 11 )$$
wherein c₁ is the number of an element in the base mesh model where the vertexes of the triangles are located, l is the serial number of the triangular surface, and n_{cl} is the total number of the triangles;
$${N}_{{c}_{1}}^{T}$$
is the transposition or the matrix of the shape function for displacement of the element in the base mesh model, and
$$γ = {Q}_{{c}_{1}}^{- 1} ( {u}^{l} ( u , v ) )$$
is the inverse transformation from the element coordinate system x to the local coordinate u in the two-dimensional square isoparametric element, i.e., the coordinates u and v in the two-dimensional isoparametric element are transformed into local coordinates x, y and z in the element of the base mesh model through the transformation; u(u, v) is a coordinate vector function in the two-dimensional square isoparametric element, and is obtained through the transformation of
$${u}^{l} = {Q}_{{c}_{1}} ( u , v ) = {\sum }_{gt = 1}^{4} {N}_{gt} ( u , v ) {x}_{gt} ,$$
N_{gt}(u, v) is the shape function for displacement of a gt^{th} node of the two-dimensional square isoparametric element, and x_{gt} is the local coordinate of a corresponding square isoparametric element node in the elements of the base mesh model;
$${u}_{u}^{l} ( u , v ) \times {u}_{v}^{l} ( u , v )$$
is the partial derivative and multiplication cross of the u coordinate vector of an l^{th} triangle with respect to the u direction and the v direction respectively; and ∥ is the determinant of a matrix, and due to the complexity of the actual surface, the functional form thereof is mostly an integral expression without an exact form, so numerical integration is carried out using Gaussian quadrature:
$$[ {F}_{{c}_{1}}^{\overline{t}} ] = {\sum }_{l = 1}^{{n}_{cl}} {\sum }_{j = 1}^{{n}_{t} = 4} {N}_{{c}_{1}}^{T} ( {x}_{j} , {y}_{j} , {z}_{j} ) \overline{t} ( {X}_{j} , {Y}_{j} , {Z}_{j} ) det {J}_{lj} {w}_{j} \qquad ( 12 )$$
wherein nₜ is the number of GIPs in the two-dimensional square isoparametric element, det Jₗⱼ is the determinant of a Jacobian transformation matrix of a j^{th} GIP of the surface load of the l^{th} triangle, and wⱼ is the integral weight of a j^{th} relative GIP position during Gaussian quadrature; and after the calculation of an element load matrix in the base mesh model is completed, a global load vector R is assembled according to the node numbers of the base mesh model;
for the imposition of Dirichlet displacement boundary conditions in the weak form, it is necessary to correct a total potential energy functional Π* by the penalty function, so as to achieve the weak imposition of displacement constraint conditions, and the following displacement constraint conditions are considered:
$$GU = V$$
wherein G is a total shape function matrix corresponding to a constrained point, U is a total node displacement vector, and V is a constraint value;
the corrected energy functional Π* is expressed as:
$${\prod }^{*} = \frac{1}{2} {U}^{T} KU - {U}^{T} R + \frac{1}{2} {α ( GU - V )}^{T} ( GU - V ) \qquad ( 14 )$$
wherein K is a global stiffness matrix, and α is a penalty function factor;
the extreme value of the corrected functional Π* is taken to obtain the following equation of static equilibrium:
$$( K + α {G}^{T} G ) U = R + α {G}^{T} V \qquad ( 15 )$$
the equation is expressed as a standard equilibrium equation:
$${K}^{*} U = {R}^{*} \qquad ( 16 )$$
wherein K* is a global stiffness matrix after the imposition of the boundary conditions, and R* is a load vector after the imposition of the boundary conditions;
the process of solving a displacement in mechanics is regarded as solving a definite solution problem ( [symbol] ) containing the boundary conditions; considering the lattice structure area \tilde{Ω} in step 1, which is hereinafter referred to as an actual smooth domain \tilde{Ω}, the global domain Ω in step 2 and an actual embedding domain Ωₑ=Ω−\tilde{Ω}, the boundary surface of Ωₑ is ∂\tilde{Ω}; and the definite solution problem is presented in a mathematical expression as:
$$( 𝓅 ) \{ \begin{matrix}- div ( \tilde{a} \cdot ∇ \tilde{u} ) + \tilde{b} \tilde{a} = \tilde{f} & in \tilde{Ω} \\ BC & on \partial \tilde{Ω}\end{matrix} \qquad ( 17 )$$
wherein div is vector divergence, ã is a diffusion tensor, ∇ is a Hamiltonian operator, ũ is an actual boundary displacement, \tilde{b} is a penalty value of the penalty function, \tilde{f} is a corrected volume force of the penalty function, and BC is an actual boundary condition; and when the boundary condition of the definite solution problem is the Dirichlet displacement boundary condition, the ũ boundary body displacement in \tilde{Ω} is simplified into a displacement u_{D} only considering the boundary surface ∂\tilde{Ω}, i.e., ũ=u_{D};
when the problem is considered using the finite cell method, since consistent meshes are used for division, the embedding domain and the actual domain are composed of consistent meshes, and the shapes thereof are different from the smooth shape of the actual embedding domain and the actual smooth domain in the original problem to the sawtooth shape; therefore, various areas originally used for calculation and analysis in the problem are changed accordingly, the actual embedding domain Ωₑ is changed to an embedding domain Ω_{e,h}, and the actual smooth domain \tilde{Ω} is changed to an actual domain \tilde{Ω}ₕΠω_{h,Σ}, wherein \tilde{Ω}ₕ is an internal domain composed of all the internal elements, ω_{h,Σ} is an area occupied by all the boundary elements, and Σ is a partial boundary surface within the boundary elements; and the problem ( [symbol] ) solved in the global domain Ω has the following general form: a specific penalty value coefficient 0<η≤1 is selected to perform calculation in the global domain Ω to obtain a problem of imposing a true equivalent displacement,
$${u}_{η}^{h} ,$$
the magnitude thereof is specifically determined by the volume of the actual smooth domain truncated by each boundary element, and the definite solution problem within the global domain Ω is transformed into:
$$( 𝓅 ) \{ \begin{matrix}- div ( a \cdot ∇ {u}_{η}^{h} ) + {bu}_{η}^{h} = f & in Ω \\ Original boundary of problem ( 𝓅 ) & on \partial \tilde{Ω} \\ Boundary of equivalent displacement {u}_{η}^{h} & on {ω}_{h , Σ}\end{matrix} \qquad ( 18 )$$
wherein a∈(L^{∞}(Ω))^{d}^{²}, b∈L^{∞}(Ω), and f∈L²(Ω), i.e., a diffusion tensor a belongs to a (L^{∞}(Ω))^{d}^{²} tensor set, a penalty coefficient b belongs to a L^{∞}(Ω) number set, and an equivalent volume force f belongs to a L²(Ω) two-directional number set; and the integral values of the simplified diffusion tensor a, penalty coefficient b and equivalent volume force f in the internal domain \tilde{Ω}ₕ are the same as those of the corresponding actual values in the actual smooth domain \tilde{Ω};
for the Dirichlet displacement boundary conditions in the finite cell method, the penalty coefficient b and the equivalent volume force f of the boundary element are respectively:
$$b = \frac{1}{η} , f = \frac{1}{η} {u}_{D} within {ω}_{h , Σ} \qquad ( 19 )$$
wherein
$$η = \frac{meas ( Σ )}{meas ( {ω}_{h , Σ}^{m} )} , meas ( {ω}_{h , Σ}^{m} )$$
is the volume of an m^{th} boundary element, and meas(Σ) is the volume of the boundary element within the boundary surface Σ; and a planar rectangular area perpendicular to the coordinate axis is defined, the boundary element is retrieved in the direction perpendicular to the rectangular area, and the imposition of the displacement boundary conditions is carried out using formula (16) to obtain the global stiffness matrix K* and the load vector R* after the imposition of the boundary conditions.

3. The efficient finite cell method for static analysis of lattice structures according to claim 2, wherein
in step 5, the displacement result U of a base mesh node is calculated through formula (10) in claim 2, and a stress-strain value is calculated; the closed surface model of the complex lattice structure is imported into Hypermesh for body-fitted mesh modeling to generate a tetrahedral body-fitted mesh model; the results on the nodes of the base mesh model are respectively mapped to the voxelization model and a tetrahedral edge-fitted model; and the physical information of an o^{th} node of the tetrahedral body-fitted mesh is denoted as pₒ, N_{Io} is the shape function for displacement of an I^{th} node in the base mesh model, and the displacement, strain and stress values of the nodes in the tetrahedral body-fitted mesh are subjected to result mapping according to N_{Io}, that is:
$${p}_{I} = {N}_{Io} {p}_{o} \qquad ( 20 )$$
the physical information pₒ comprises node displacement, strain and stress values; and a stress smoothing method is adopted, and when the degree of smoothing grinding is considered to be a(0<a<1), a smoothing grinding formula is:
$$\{ \begin{matrix}{σ}_{I}^{r} = {\sum }_{k = 1}^{{n}_{k}} \frac{{\sum }_{g = 1}^{{n}_{g}} {β}_{g}^{{c}_{2}}}{{\sum }_{k = 1}^{{n}_{k}} {\sum }_{g = 1}^{{n}_{g}} {β}_{g}^{k}} {σ}_{I}^{{c}_{2}} & if 0 < \tilde{ϵ} \leq ϵ \\ {σ}_{I}^{r} = {σ}_{I}^{{c}_{2}} & if ϵ < \tilde{ϵ}\end{matrix} \qquad ( 21 )$$
wherein
$${σ}_{I}^{{c}_{2}}$$
is the stress value of the I^{th} node in a c₂^{th} element of the base mesh model, σ_{I}^{r} is a smoothed stress value, nₖ is the number of tetrahedral meshes containing the I^{th} node,
$${β}_{g}^{{c}_{2}}$$
is a penalty function index of a g^{th} GIP in the c₂^{th} element,
$${β}_{g}^{k}$$
is a penalty function index or a g^{th} GIP in the k^{th} element, \tilde{ϵ} is the proportion of the stress value of the node corresponding to the c₂^{th} element in the global stress variation, no smoothing is performed when the index \tilde{ϵ} of the node is less than a defined index ϵ, and \hat{ϵ} is defined as:
$$\tilde{ϵ} = \frac{\vert {σ}_{I}^{r} - {σ}_{I}^{{c}_{2}} \vert}{\vert {σ}_{g , max} - {σ}_{g , min} \vert} \qquad ( 22 )$$
wherein σ_{g,max} is global maximum stress, σ_{g,min} is global minimum stress, and |⋅| represents taking an absolute value;
since the external elements are removed in step 2, mesh nodes located outside the base mesh area Ω_{F} will exist on the tetrahedral body-fitted mesh; since the use of the shape function for displacement of the elements requires the interpolated points to be within the elements of the base mesh area Ω_{F}, the nodes located outside the base mesh area Ω_{F} cannot be directly subjected to result mapping through the shape function for displacement N_{Io}, and such problems are solved based on the basic principles of the natural neighbor interpolation (NNI) in the method; and if a node on a tetrahedral body-fitted mesh is outside the base mesh area Ω_{F} when the retrieved element is subjected to result mapping, the global coordinate system X, Y, Z of the node is listed separately, all elements close to the node are retrieved, and the distance [Cen] between the geometric center position d of the elements and the node is calculated as:
$$[ Dis ] = \sqrt{{( ( X , Y , Z ) - [ Cen ] )}^{2}} \qquad ( 23 )$$
the boundary element closest to the node is judged by the distance [Dis], and the displacement, strain and stress values of the node within the boundary element are subjected to result mapping to obtain a smooth result output, so as to solve the problem of stress result distortion.
